(19) United States
(12) Patent Application Publication
(10) Pub. No.: US 2014/0258814 A1
(43) Pub. Date: Sep. 11, 2014

(54) METHOD OF TRANSFERRING EXTRINSIC INFORMATION OF TURBO DECODER AND APPARATUS USING THE SAME

(71) Applicant: Electronics and Telecommunications Research Institute, Daejeon (KR)

(72) Inventors: In-San JEON, Daejeon (KR); Hyuk KIM, Daejeon (KR); Seong-Min KIM, Daejeon (KR)

(73) Assignee: Electronics and Telecommunications Research Institute, Daejeon (KR)

(21) Appl. No.: 14/194,235

(22) Filed: Feb. 28, 2014

(30) Foreign Application Priority Data
Mar. 6, 2013 (KR) 10-2013-0023857

(51) Int. Cl. H04L 1/00; H03M 13/25

(52) U.S. Cl. CPC H04L 1/0054; H03M 13/258
USPC 714/780

(57) ABSTRACT

Disclosed herein is a method and apparatus for transferring extrinsic information of a turbo decoder. In the method of transferring the extrinsic information of the turbo decoder according to the present invention, Log-Likelihood Ratio (LLR) values for input bits of the turbo decoder are calculated. The LLR values are transferred as extrinsic information values.

### CROSS REFERENCE TO RELATED APPLICATION

This application claims the benefit of Korean Patent Application No. 10-2013-0023857, filed on Mar. 6, 2013, which is hereby incorporated by reference in its entirety into this application.

### BACKGROUND OF THE INVENTION

1. Technical Field

The present invention relates generally to a turbo decoder and, more particularly, to technology capable of transferring extrinsic information of a turbo decoder using a minimum memory space.

2. Description of the Related Art

The physical layer of a plurality of mobile communication systems, such as 3rd Generation Partnership Project (3GPP) Long Term Evolution (LTE) systems, uses turbo codes so as to correct errors occurring on channels, and a receiver uses a turbo decoder so as to decode a received signal.

One of obstacles interfering with faster communication in high-speed mobile communication systems is a turbo decoder having to perform a large amount of computation.

Generally, a high-speed turbo decoder is implemented using a high radix. However, when the turbo decoder is implemented using a high radix, the number of extrinsic information values increases, and then a problem arises in that the memory space for storing extrinsic information increases.

A paper published by Ju Won Jung et al. in 2005 and entitled “Design and Architecture of Low-Latency High-Speed Turbo Decoders” discloses a structure for transferring extrinsic information of a radix-4 turbo decoder using four Log-Likelihood (LL) values, that is, LL00, LL01, LL10, and LL11.

FIG. 1 is a block diagram showing a conventional turbo decoder.

A symbol interleaver and a symbol deinterleaver shown in FIG. 1 have a similar structure. Of these components, the symbol interleaver is configured, as shown in FIG. 2. L_{c}(Xⱼ⁰⁰), L_{c}(Xⱼ⁰¹), L_{c}(Xⱼ¹⁰), and L_{c}(Xⱼ¹¹) and Lₑ(dₖ⁰⁰), Lₑ(dₖ⁰¹), Lₑ(dₖ¹⁰), and Lₑ(dₖ¹¹) shown in FIG. 1 correspond to LL′00, LL′01, LL′10, and LL′11 shown in FIG. 2.

The size of memory required for LL00 is half of the information length N. For LL00, LL01, LL10, and LL11, four memories, each corresponding to half of the information length N, are required. Therefore, there is a problem in that, in order to transfer extrinsic information using four Log-Likelihood (LL) values, memory having a size (2N) which is twice the memory size N, required to transfer extrinsic information in a typical radix-2 structure, is required.

Accordingly, new technology is required which is capable of transferring extrinsic information using only a small memory space in a turbo decoder having a high radix such as radix-4.

### SUMMARY OF THE INVENTION

Accordingly, the present invention has been made keeping in mind the above problems occurring in the prior art, and an object of the present invention is to minimize an increase in the size of memory caused by an increase in the number of extrinsic information values in a turbo decoder having a high radix.

For example, the present invention is intended to transfer extrinsic information in a radix-4 turbo decoder using only a memory space identical to that of a radix-2 turbo decoder, unlike a conventional scheme in which the extrinsic information values of a typical radix-4 turbo decoder generally require a memory size that is twice that of a radix-2 turbo decoder.

Another object of the present invention is to minimize an increase in memory space even in a turbo decoder having a high radix, thus minimizing an increase in cost when a System on Chip (SoC) for the turbo decoder is implemented.

In accordance with an aspect of the present invention to accomplish the above objects, there is provided a method of transferring extrinsic information of a turbo decoder, including calculating Log-Likelihood Ratio (LLR) values for input bits of the turbo decoder; and transferring the LLR values as extrinsic information values.

Preferably, calculating the LLR values may include calculating Log-Likelihood (LL) values for the input bits of the turbo decoder; and calculating the LLR values using the LL values.

Preferably, a number of LLR values may be less than a number of LL values.

Preferably, calculating the LLR values using the LL values may include comparing two of the LL values with each other and outputting larger values; and obtaining differences between two of the output values and then calculating the LLR values.

Preferably, the turbo decoder may be a radix-4 turbo decoder, the number of LL values may be 4, and the number of LLR values may be 2.

In accordance with another aspect of the present invention to accomplish the above objects, there is provided an apparatus for transferring extrinsic information of a turbo decoder, including a Log-Likelihood Ratio (LLR) calculation unit for calculating LLR values for input bits of the turbo decoder; and an extrinsic information transfer unit for transferring the LLR values as extrinsic information values.

Preferably, the LLR calculation unit may include a Log-Likelihood (LL) calculator for calculating LL values for the input bits of the turbo decoder; and an LLR calculator for calculating the LLR values using the LL values.

Preferably, a number of LLR values may be less than a number of LL values.

Preferably, the LLR calculator may include a maximum value calculation unit for comparing two of the LL values with each other and outputting larger values; and a subtraction unit for obtaining differences between two of the values output from the maximum value calculation unit, and then calculating the LLR values.

Preferably, the turbo decoder may be a radix-4 turbo decoder, the number of LL values may be 4, and the number of LLR values may be 2.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram showing a conventional turbo decoder;

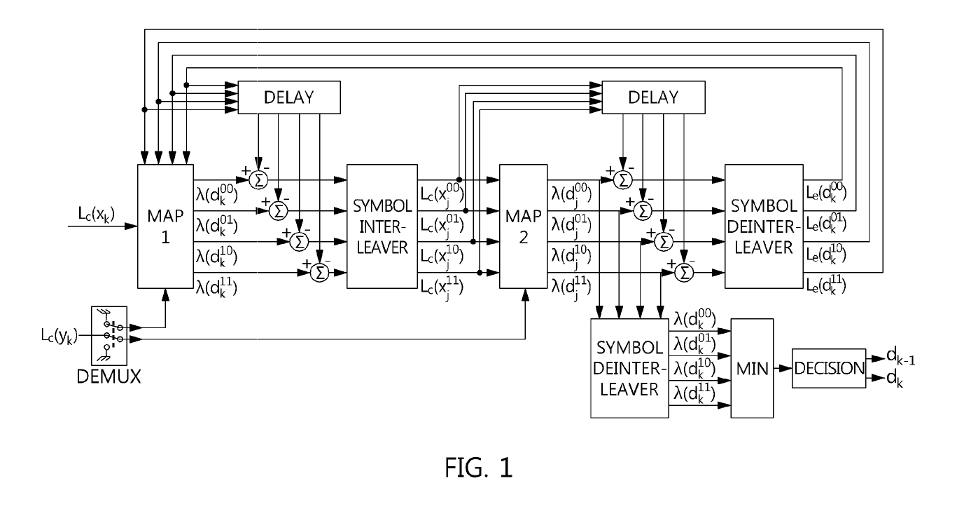

FIG. 2 is a block diagram showing the structure of a symbol interleaver shown in FIG. 1;

FIG. 3 is an operation flowchart showing a method of transferring extrinsic information of a turbo decoder according to an embodiment of the present invention; and

FIG. 4 is a block diagram showing an apparatus for transferring extrinsic information of a turbo decoder according to an embodiment of the present invention.

### DESCRIPTION OF THE PREFERRED EMBODIMENTS

The present invention will be described in detail below with reference to the accompanying drawings. In the following description, redundant descriptions and detailed descriptions of known functions and elements that may unnecessarily make the gist of the present invention obscure will be omitted. Embodiments of the present invention are provided to fully describe the present invention to those having ordinary knowledge in the art to which the present invention pertains. Accordingly, in the drawings, the shapes and sizes of elements may be exaggerated for the sake of clearer description.

The present invention may be applied to typical radix-R (R=2ⁱ, i=2, 3, . . . ), such as radix-8, as well as radix-4, but the present invention will be described below based on radix-4 for the convenience of description.

Equations for a Max-Log-maximum a posteriori (MAP) algorithm) for radix-2 are given by the following Equations (1) to (4):

$$\begin{matrix}{D}_{i} ( {R}_{k} , m ) = ( \frac{2}{{σ}^{2}} ( {x}_{k} i + {y}_{k} {Y}_{k}^{i} ( m ) ) ) & ( 1 ) \\ {A}_{k}^{i} ( m ) = {D}_{i} ( {R}_{k} , m ) + {max}_{j = 0}^{1} [ {A}_{k - 1}^{j} ( {S}_{b}^{j} ( m ) ) ] & ( 2 ) \\ {B}_{k}^{i} ( m ) = {max}_{j = 0}^{1} [ {B}_{k + 1}^{j} ( {S}_{f}^{j} ( m ) ) + {D}_{j} ( {R}_{k + 1} , {S}_{f}^{j} ( m ) ) ] & ( 3 ) \\ L ( {d}_{k} ) = {max}_{m = 0}^{{2}^{v} - 1} ( {A}_{k}^{1} ( m ) + {B}_{k}^{1} ( m ) ) - {max}_{m = 0}^{{2}^{v} - 1} ( {A}_{k}^{0} ( m ) + {B}_{k}^{0} ( m ) ) & ( 4 )\end{matrix}$$

Equations (1) to (4) are described in detail in a paper published by Pietrobon et al. in 1994 and entitled “A simplification of the modified Bah1 decoding algorithm for systematic convolutional codes,” and thus a detailed description thereof will be omitted here.

Equation (1) is identical to equation (39) in the paper by Pietrobon et al., Equations (2) and (3) respectively correspond to equations (37) and (38) of the paper, and Equation (4) corresponds to equation (34) of the paper. However, technology in the paper uses an E function, but technology in the present specification uses ‘max.’

A radix-4 structure employs a scheme for processing two input information bits as a single unit. If two types of branch metric components have been previously calculated and input, equations for log-likelihood (LL) values in the radix-4 structure may be represented as follows:

A_{K}^{I}(m)=D_{I}(Rₖ, m)+maxⱼ₌₀³ A_{K-1}^{J}(S_{b}^{J}(m)) (5)

Bₖ^{I}(m)=max_{J=0}³ [B_{K}^{J}(S_{f}^{I}(m))+D_{J}(R_{K}, S_{f}^{I}(m))] (6)

LL(d_{K}=I)=maxₘ₌₀²^{^{v}}⁻¹(A_{K}^{I}(m)+B_{K}^{I}(m)) (7)

In Equations (5) to (7), K denotes a single stage into which two stages are combined, and I and J denote values obtained by representing 2-bit input values 00, 01, 10, and 11 by integers 0, 1, 2, and 3 because the equations correspond to the radix-4 structure and then use the 2-bit input values. Other variables are identical to those used in Equations (1) to (4).

As described above, if LL values are transferred as the extrinsic information of the turbo decoder, memory having a memory size that is twice the information length N is required in the case of the radix-4 structure.

Therefore, the present invention transfers extrinsic information using Log-Likelihood Ratio (LLR) values. Therefore, even in the case of the radix-4 structure, it is possible to transfer extrinsic information even using memory having a memory size identical to the information length N, thus enabling the turbo decoder to be implemented using only memory having ½ of the memory size required in an LL scheme.

Hereinafter, preferred embodiments of the present invention will be described in detail with reference to the attached drawings.

In order to reduce an increase in memory required to transfer extrinsic information, extrinsic information may be transferred using one memory per stage if Log-Likelihood (LL) equations are newly developed, as given in the following equations, and LLR values are calculated and stored based on the LL equations.

It is very complicated to calculate LLR values in the radix-4 structure without calculating LL values. Therefore, in the present invention, LL values for the respective stages are obtained among LL values, and the ratios of the obtained LL values are calculated, and then LLR values are obtained.

Values of LL(0), LL(1), LL(2), and LL(3) for the input bits 00, 01, 10, and 11 of the radix-4 turbo decoder may be represented by the following Equations (8), (9), (10), and (11), respectively:

LL(d_{K}=00)=maxₘ₌₀²^{^{v}}⁻¹(A_{K}^{I=00}(m)+B_{K}^{I=00}(m) (8)

LL(d_{K}=01)=maxₘ₌₀²^{^{v}}⁻¹(A_{K}^{I=01}(m)+B_{K}^{I=01}(m)) (9)

LL(d_{K}=10)=maxₘ₌₀²^{^{v}}⁻¹(A_{K}^{I=10}(m)+B_{K}^{I=10}(m)) (10)

LL(d_{K}=11)=maxₘ₌₀²^{^{v}}⁻¹(A_{K}^{I=11}(m)+B_{K}^{I=11}(m)) (11)

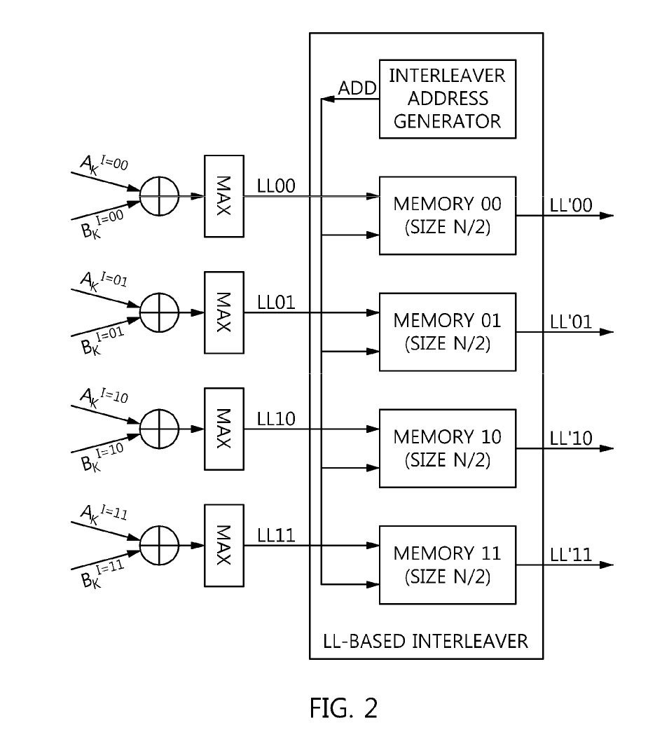

The four LL values calculated by the above Equations (8) to (11) correspond to LL00, LL01, LL10, and LL11, respectively, shown in FIG. 2.

Below, a process for obtaining LLR values for respective bits using the LL values of the radix-4 turbo decoder will be described in detail.

When LL values for the respective input bits are obtained using Equations (8), (9), (10), and (11), LL(0x), LL(1x), LL(x0), and LL(x1) are obtained by the following Equations (12), (13), (14), and (15), where x denotes ‘don't care.’

LL(d_{K}=0x)=max (LL(d_{K}=00), LL(d_{K}=01)) (12)

LL(d_{K}=1x)=max (LL(d_{K}=10), LL(d_{K}=11)) (13)

LL(d_{K}=x0)=max (LL(d_{K}=00), LL(d_{K}=10)) (14)

LL(d_{K}=x1)=max (LL(d_{K}=01), LL(d_{K}=11)) (15)

When LLR values for the respective two input bits are calculated using LL values calculated for the respective bits via Equations (12) to (15), the following Equations (16) and (17) are obtained.

LLR(d_{K}=ix)=LL(d_{K}=1x)−LL(d_{K}=0x) (16)

LLR(d_{K}=xj)=LL(d_{K}=x1)−LL(d_{K}=x0) (17)

In Equations (16) and (17), x denotes ‘don't care,’ and i and j denote a first input bit and a second input bit, respectively.

That is, in Equation (16), LLR(d_{K}=ix) corresponds to a difference between a probability that the first input bit will be 1 and a probability that the first input bit will be 0, and corresponds to an LLR value for the first input bit. Further, in Equation (17), LLR(d_{K}=xj) corresponds to a difference between a probability that the second input bit will be 1 and a probability that the second input bit will be 0, and corresponds to an LLR value for the second input bit.

If the above Equations (16) and (17) are represented using A and B, the following Equations (18) and (19) are obtained.

LLR(d_{K}=ix)=max [ maxₘ₌₀²^{^{v}}⁻¹(A_{K}^{I=10}(m)+B_{K}^{I=10}(m), maxₘ₌₀²^{^{v}}⁻¹(A_{K}^{I=11}(m)+B_{K}^{I=11}(m))]−max [ maxₘ₌₀²^{^{v}}⁻¹(A_{K}^{I=00}(m)+B_{K}^{I=00}(m), maxₘ₌₀²^{^{v}}⁻¹(A_{K}^{I=01}(m)+B_{K}^{I=01}(m))] (18)

LLR(d_{K}=xj)=max [ maxₘ₌₀²^{^{v}}⁻¹(A_{K}^{I=01}(m)+B_{K}^{I=01}(m), maxₘ₌₀²^{^{v}}⁻¹(A_{K}^{I=11}(m)+B_{K}^{I=11}(m))]−max [ maxₘ₌₀²^{^{v}}⁻¹(A_{K}^{I=00}(m)+B_{K}^{I=00}(m), maxₘ₌₀²^{^{v}}⁻¹(Aₖ^{I=10}(m)+Bₖ^{I=10}(m))] (19)

In this way, when extrinsic information is transferred based on the LLR values, the size of interleaver memory to be used may be reduced to half compared to the case where extrinsic information is transferred based on LL values.

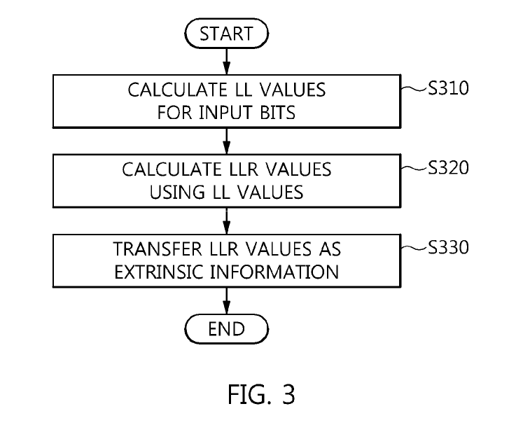

FIG. 3 is an operation flowchart showing a method of transferring extrinsic information of a turbo decoder according to an embodiment of the present invention.

Referring to FIG. 3, in the method of transferring the extrinsic information of the turbo decoder according to the embodiment of the present invention, Log-Likelihood (LL) values for input bits of the turbo decoder are calculated at step S310.

Further, in the method of transferring extrinsic information of the turbo decoder according to the embodiment of the present invention, Log-Likelihood Ratio (LLR) values are calculated using the LL values at step S320.

In this case, the number of LLR values may be less than the number of LL values. For example, the number of LL values may be 4 and the number of LLR values may be 2.

Step S320 may include the step of comparing two of the LL values and outputting larger values; and the step of obtaining differences between two of the output values and calculating the LLR values.

Further, in the method of transferring the extrinsic information of the turbo decoder according to the embodiment of the present invention, the LLR values are transferred as extrinsic information values at step S330.

In this case, the turbo decoder may be a radix-4 turbo decoder, but it is not limited to such a radix-4 structure in the technical spirit of the present invention.

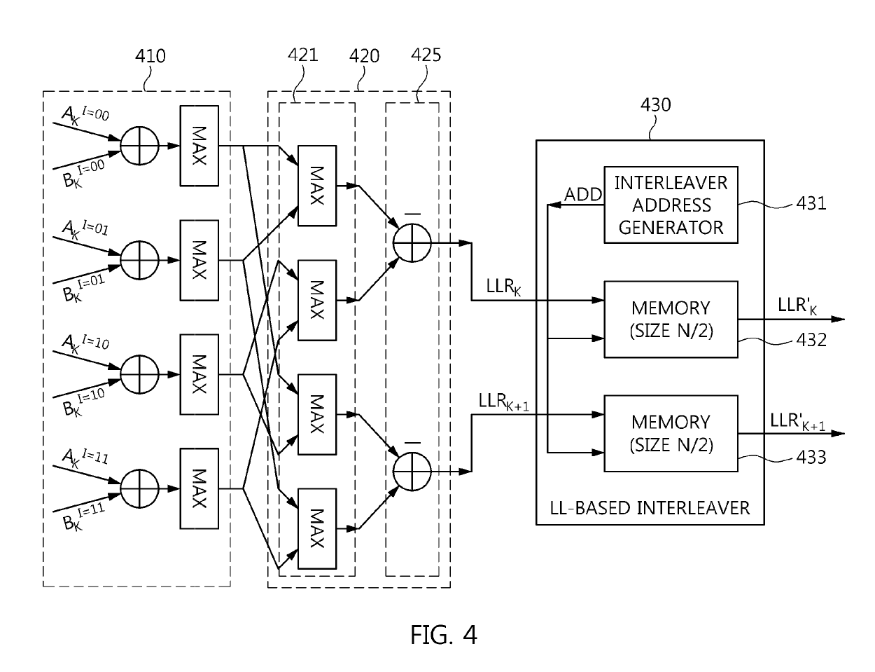

FIG. 4 is a block diagram showing an apparatus for transferring extrinsic information of a turbo decoder according to an embodiment of the present invention.

Referring to FIG. 4, the apparatus for transferring the extrinsic information of the turbo decoder according to the embodiment of the present invention includes an LL calculator 410, an LLR calculator 420, and an extrinsic information transfer unit 430.

In this case, the LL calculator 410 and the LLR calculator 420 may correspond to an LLR calculation unit described in the accompanying claims.

The LL calculator 410 calculates LL values for the input bits of the turbo decoder.

The LL calculator 410 performs the same function as that of FIG. 2, and thus a detailed description thereof will be omitted.

The LLR calculator 420 calculates LLR values using the LL values.

The LLR calculator 420 may include a maximum value calculation unit 421 and a subtraction unit 425.

The maximum value calculation unit 421 compares two of the LL values with each other and outputs larger values. That is, the maximum value calculation unit 421 performs functions corresponding to Equations (12) to (15).

The subtraction unit 425 obtains differences between two of the values output from the maximum value calculation unit 421 and then calculates LLR values LLRₖ and LLRₖ₊₁. The values LLRₖ and LLRₖ₊₁ of FIG. 4 correspond to the LLR values shown in Equations (18) and (19), respectively.

The extrinsic information transfer unit 430 transfers the LLR values as extrinsic information values.

In particular, although an example in which the extrinsic information transfer unit 430 is an interleaver is shown in FIG. 4, the technical spirit of the present invention is not limited to the case where the extrinsic information transfer unit 430 is an interleaver.

The extrinsic information transfer unit 430 corresponding to an LLR-based interleaver includes an interleaver address generator 431 and two memories 432 and 433.

In this case, the size of each of the memories 432 and 433 may be a value obtained by dividing information length N by 2.

The memories 432 and 433 perform interleaving by generating output values depending on the address generated by the interleaver address generator 431.

In this case, the number of LLR values may be less than the number of LL values. For example, in the case of radix-4, the number of LLR values may be 2, and the number of LL values may be 4.

In accordance with the present invention, an increase in the size of memory caused by an increase in the number of extrinsic information values in a turbo decoder having a high radix may be minimized.

Further, the present invention may minimize an increase in memory space even in a turbo decoder having a high radix, thus minimizing an increase in cost when a System on Chip (SoC) of the turbo decoder is implemented.

As described above, in the method and apparatus for transferring extrinsic information of a turbo decoder according to the present invention, the configurations and schemes in the above-described embodiments are not limitedly applied, and some or all of the above embodiments can be selectively combined and configured so that various modifications are possible.

What is claimed is:

1. A method of transferring extrinsic information of a turbo decoder, comprising:
calculating Log-Likelihood Ratio (LLR) values for input bits of the turbo decoder; and
transferring the LLR values as extrinsic information values.

2. The method of claim 1, wherein calculating the LLR values comprises:
calculating Log-Likelihood (LL) values for the input bits of the turbo decoder; and
calculating the LLR values using the LL values.

3. The method of claim 2, wherein a number of LLR values is less than a number of LL values.

4. The method of claim 3, wherein calculating the LLR values using the LL values comprises:
comparing two of the LL values with each other and outputting larger values; and
obtaining differences between two of the output values and then calculating the LLR values.

5. The method of claim 4, wherein:
the turbo decoder is a radix-4 turbo decoder, and
the number of LL values is 4, and the number of LLR values is 2.

6. An apparatus for transferring extrinsic information of a turbo decoder, comprising:
a Log-Likelihood Ratio (LLR) calculation unit for calculating LLR values for input bits of the turbo decoder; and
an extrinsic information transfer unit for transferring the LLR values as extrinsic information values.

7. The apparatus of claim 6, wherein the LLR calculation unit comprises:
a Log-Likelihood (LL) calculator for calculating LL values for the input bits of the turbo decoder; and
an LLR calculator for calculating the LLR values using the LL values.

8. The apparatus of claim 7, wherein a number of LLR values is less than a number of LL values.

9. The apparatus of claim 8, wherein the LLR calculator comprises:
a maximum value calculation unit for comparing two of the LL values with each other and outputting larger values; and
a subtraction unit for obtaining differences between two of the values output from the maximum value calculation unit, and then calculating the LLR values.

10. The apparatus of claim 9, wherein:
the turbo decoder is a radix-4 turbo decoder, and the number of LL values is 4, and the number of LLR values is 2.
